(19) United States
(12) Patent Application Publication
(10) Pub. No.: US 2007/0273402 A1
(43) Pub. Date: Nov. 29, 2007

(54) Relational signaling and medium for high speed serial communications

(76) Inventor: Jon David Zethmayr, Mauston, WI (US)

Correspondence Address: DAVID ZETHMAYR aka JON DAVID ZETHMAYR, W4587 COUNTY ROAD G E, MAUSTON, WI, 53948, US

(21) Appl. No.: 11/416,863

(22) Filed: May 2, 2006

(51) Int. Cl. H03K 17/16; H03K 19/003

(52) U.S. Cl. 326/30

(57) ABSTRACT

Three or more wires are configured as a differential “skein” (FIG. 1). Symbols may use equal voltages as well as differing voltages. “Softpairs” (132 142 152) of a “skein” are discriminated in differential mode by “relational comparators” (200), exploiting hysteresis in differential comparators to detect voltage near-equality versus signed difference. Data rates up to 3 bits/transition on three wires, 6 b/tr on four wires, 9 b/tr on five wires.

### CROSS-REFERENCE TO RELATED APPLICATIONS

(N/A)

### FEDERALLY SPONSORED RESEARCH OR DEVELOPMENT STATEMENT

None involved.

### REFERENCE TO SEPARATE LISTINGS OR TABLES

No material is submitted apart from the present document.

### BACKGROUND

1. Field of Invention

Electronic serial communications, specifically a method of using multiple wires, and a method of signaling.

2. Prior Art

Electronic devices have a universal, two-edged problem simply because they have wires. Wires are antennas, even though we most often don't want them to be. Antennas both radiate energy and soak it up. Outside the wire, what moves is electromagnetic fields. Inside the wire, what moves is homeless electrons, wandered from atoms of metal.

Unwanted emissions are called electromagnetic interference (EMI). Internal currents induced from outside, the art calls “noise.”

There is a well-known technique to get rid of most of this “unintentional two-way antenna” problem. That is to arrange wires and circuit traces in intimately parallel, “fully differential” pairs. A differential pair provides a complete round-trip path for the currents we intend as meaningful signals. The round-trip path includes a resistor at every bitter end, value chosen to prevent energy reflections.

This works in the radiative direction because signal currents now generate fields of opposite polarization. When that happens the fields buck, nearly canceling each other. In the soakup-antenna direction it works because EMI from outside induces nearly equal currents in the same direction in the two traces. This we call common-mode noise.

But our intentional signal current flows in opposite directions in the differential pair. Common-mode noise helps the signal current along in the one wire, while bucking it in the other. All the aiding and bucking adds up to (nearly) no net resultant effect on total signal current.

The aiding and bucking is visible on the pair as changes in the two absolute voltage levels. So to secure the common-mode effect advantage, we make sure to do one more thing. We require the receiving detectors, or discriminators, to pay no attention to particular, referenced voltages. We make them sensitive only to voltage differences.

This differential-pair technique is so effective it has long been regarded as the essential safe haven for signals. The new idea here will be to take a step away from the pair and retain the same signal protection in more than two parallel conductors.

There is a hidden price to the fully-differential strategy. The “intimately parallel” conductors are (1) close together, with (2) a high energy barrier between. This makes a capacitor, an energy-hoarding arrangement. Energy thus hoarded can distort our intended signals in a different way, called “line polarization,” mixing some of the stored energy with signal energy.

Line polarization and field polarization, though related, are separate practical matters. The phenomenon of concern in high-speed serial communications is line polarization.

Communications traffic has burgeoned in the past few decades. Most of it is carried, for some of its travel, by two signaling methods-8 b/10 b, and pulse amplitude modulation (PAM5). Both methods take the differential pair (FIG. 1pa) as the medium. 8 b/10 b is slower, and more reliable over long distances. PAM5 has much more severe distance limitations than 8 b/10 b.

8 b/10 b uses four wires, terminated as two differential pairs, as its unitary medium. The second b of “8 b/10 b” refers to binary encoding. That is, just two signal states are used: clockwise current flow, or counterclockwise. The receiving device is intentionally not equipped to directly recognize no current as a meaningful difference. It discriminates only the direction of current, looking at the voltage effects of the flow. The method is robust against interference and degradation because of this simplicity. The ‘8/10’ of the name says that an eight-bit granule of data is conveyed in ten signal transitions. The per-transition data rate on 8 b/10 b is just under 1 bit/tr on two pairs.

The PAM5 method takes a single differential pair as its unitary medium. In PAM5, five voltage levels are available for signaling—an arity of 5. Receivers discriminate voltage differences, but now the size of the difference is meaningful as well as polarity (direction, sense). A no current state is discriminated as well (zero voltage difference). These receive-side arrangements confer increased encoding freedom. More data load is carried in each symbol transition in PAM5 than in 8 b/10 b. In 1000Base-T (Gigabit Ethernet) arrangement, PAM5 combines four differential pairs as a channel. Transferring 2 bits per symbol on each pair, the channel data rate is 8 bits per transition [InterOpPCS].

PAM5 encoding is structured on trellis coding. Decoding is done in Viterbi decoding technique [ViOm1979], involving computing path costs through the trellis structure.

Worst-case test cables used in qualifying commercial PAM5 devices for Gigabit Ethernet are under two meters in length [NilssonInOP]. Lines longer than 55 meters remain the territory of 8 b/10 b on UTP (unshielded twisted pairs) and fiber optic channels. 100 meters is the current target milestone of PAM5 development efforts.

3. Objects and Advantages

The chief object of the invention is to serve as a communications medium for multi-bit per transition data transfer. The new idea is that differential signaling in multi-voltages is available once the discrete-pair principle is let go, changing from aggregated differential pairs to a “relational skein” as the medium. The multi-voltage symbols need not strictly use unequal voltages—the max-arity alphabet—but may expand the symbol alphabet with symbols where some of the voltages are the same. With such expansion, differential signaling is widened to “relational” signaling.

Another object and advantage is to discriminate symbols without resorting to analog-to-digital conversion, a time-costly process compared to how fast a differential comparator settles on a result.

On four wires, the symbol space available in “relational” signaling (arity 4) exceeds even that of PAM5 with its 5-ary (quinary) Trellis encoding. PAM5's unitary medium, one differential pair, natively affords 2-bit data granularity.

“Relational” signaling on a “skein” of five wires offers 8 or 9 bits/tr, an advantage in cable cost compared to the eight wires of Gigabit Ethernet. When bandwidth is more important than cable cost, ten wires deployed as a single channel of two 5-wire “skeins” offer a 16-bit/tr data rate. This may be expanded (with arity 5) to 18 bits/tr for shorter distances, on the order of 50 meters.

A further advantage over PAM5 is that “relational” discrimination circuitry does not rely on maintaining a marker voltage reference at the receiving end but looks only at voltage differences pairwise, a simpler principle that can be expected to be more robust, especially over long-haul lines.

An object of the invention is to enjoy greater encoding freedom without giving up the inherent common-mode noise rejection (CMR) property of the classical differential pair. This is attained, on the observation that analysis given above of common-mode induced currents in conductors configured as a “skein” is equally valid on a “skein” of degree 2—a single differential pair, that is—and “skeins” of higher order. The price for retaining the CMR advantage, as noted above, will be to restrict discrimination strategy to differential means—that is, not relying on reference voltages. This may enable operation over some range of distances now served only by 8 b/10 b on ATM lines, where line polarization and unequal signal attenuation (energy loss) are the chief difficulties.

A broader novel teaching is that differential-mode detection may be arranged to make “relational” discriminations. This means adding nearly equal to the differential outcomes greater and less. In turn this secures the advantage of a larger symbol alphabet of voltage combinations for signaling and thereby higher data rates.

It is line polarization—the long complex capacitor nature of a multi-wire cable—that challenges the art the most, because of its ever-shifting, stochastic nature: communications activity on the medium creates the problem, moment-to-moment, to different degree, while the termination resistors somewhat bleed it away.

8 b/10 b technology counters the polarization challenge with a two-prong strategy involving (1) defining a working wordset that minimizes the effect—sending only those ten-transition combinations that have balanced and nearly balanced DC polarity over time—and (2) keeping a running score on the DC polarity imbalance for deciding when to send one of the compensating null-semantic words—called “commas”—chosen to counter the polarization.

While costly because of the multi-polar “skein” medium, a running-score strategy similar to that of 8 b/10 b is certainly feasible in “relational skein” technology and is not deprecated. Because polarization affects longer lines more severely, a strategy of scoring polarization only transmit-side suffers from lack of operational feedback. A receive-side polarization strategy will be detailed as preferred embodiment.

The Line Polarization Problem

“Relational” signaling offers several techniques to address the line polarization problem:

(1) A transmission-side rule requiring impressed symbol voltages to be in static DC balance (adding to zero) during routine data transfer (that is, apart from bus bidding, if such is in the protocol) makes available a basis for compensating for line polarization on the receiving end. This is expected to increase the distances practical for reliable communications.

Graded Fallbacks

(2) A graded fallback flexibility is available, with arity choices and a depolarizing special symbol. The most robust and slowest mode, “granny gear,” is, in 4-wire embodiment, roughly comparable to the binary differential signaling of two separate pairs (8 b/10 b), temporarily choosing robustness in a trade-off against speed. In “granny,” we insert a null-semantic symbol, <Depo> (all conductors grounded) after every semantic symbol as a depolarizing episode. The per-transition bit rate in “granny” is about the same as 8 b/10 b.

(3) “Granny gear” makes practical a self-tuning feedback strategy of occasionally probing line conditions with graduated samples of “gearing” or arity options to support the decision of how often to insert depolarizing episodes, managing these administrative exchanges in “granny gear.”

The PAM5 method has recently acquired a graded fallback capability—U.S. Pat. No. 0,206,578 (2003) “Fractional bit rate encoding in a pulse amplitude modulated (PAM) communications system” [Fractional2003].

(4) “Relational” signaling is optionally asynchronous. This would allow adjusting the time spent in mid-message depolarizing episodes, as conditions require.

Feedback Shift Register (FSR) Technique

An allied prior-art strategy against polarization, is feedback shift register (FSR) technique-scrambling symbols by XOR-ing their granules (before symbol lookup, send-side) with an ever-changing pseudo-random tuple. The randomizing tuple is carried in a feedback shift register, shifted identically for every new symbol by sending and receiving parties. Pseudo-randomizing tends to wash out degenerate regularities that make for trouble in two areas: EMI and polarization.

FSR is readily applied in “relational skein” apparatus and is preferred embodiment. Pseudo-randomizing by FSR is well-understood technology, familiar to practitioners. It involves initializing a feedback shift register to a known state at agreed events—for example, at every <end-of-CRC> special symbol, or every <end-of-transmission> special.

Punctuated Bidding Advantage: Bus Scalability

A further advantage of a “relational skein” medium is a new degree of smooth scalability in the matter of how many devices, messages or priorities may be accommodated in a given collision space on a network. Bus designs have had to set a fixed bit width for whatever kind of denoted entity—device address, message id (CANbus), or priority—is chosen to be the basis on which bidding proceeds. This has meant that to accommodate greater space (more bits) in the denotation of interest requires specifying a higher grade of implementation, incompatible with existing implementations.

The ability of “skein” medium to float some conductors while driving others makes possible a dimension of bidding for the talking privilege that is not available on, for example, two hardpaired differential pairs: “punctuated bidding.” Several stages of bidding might be defined, each of variable length because a device can now claim the bid early at each phase. The variable length makes this strategy arbitrarily scalable. As a further advantage, it avoids the need for assigning artificially unique priorities, because later stages (such as unique device ID) can be used to resolve the bid.

Punctuated Bidding Advantage: Message Starvation

One way to exploit a “skein's” flexible floatability would be to define a “bus hunger” phase as the first bidding phase. Two advantages would accrue: a graceful, non-arbitrary way of solving the message starvation problem, for meeting the can't-wait demands of isochronous feeds (audio, video), and as a graded early-warning metric of bus traffic overload as stakeholders evaluate adequacy of their infrastructure. The option to report “bus hunger” escalations for management attention does not figure (to my knowledge) in existing PHY-LINK interface specifications.

Asynchronous Advantage: Frequency Dithering to Reduce EMI

A further advantage accrues from the freely asynchronous way the receiving converter operates. This option makes it easy to apply the technique of dithering the fundamental frequency of transmissions, to the object of reducing EMI. Frequency dithering (also called “spread spectrum” technique, ignoring the earlier “frequency-hopping” meaning of that term) has recently been applied in AC power distribution to the same object.

### SUMMARY

The invention considers three, four or more wires (or circuit board traces, or on-chip conductors) in an electrically symmetric structure as a serial communications medium (bus or point-to-point channel). This unitary medium is termed a “skein.” “Skein” medium makes for rich variety of signal combinations available for encoding. Such variety is exploited to enhance bandwidth usage at frequencies in FCC-approved use, resulting in multi-bit-per-transition data transfer speeds.

“Skein” configuration takes a “softpair” view of the multi-wire medium, in which each of the conceptual pairs of conductors is analyzed separately in its own “relational” or “LEG” comparator (LESS-EQUAL-GREATER), in parallel fashion, so that final decoding is done simply by a lookup table rather than by a path-cost-through-a-lattice algorithm (PAM5). Relational information (>, =, <) is retrieved (optionally) from the medium directly into the digital domain, using differential mode detectors only, without intermediate analog-to-digital conversion.

### FIGURES

FIG. 1 Impedance-match termination for 4-wire “relational skein”

FIG. 1a Impedance-match termination for 3-wire “relational skein”

FIG. 1b Impedance-match termination for 5-wire “relational skein”

FIG. 1pa Two classical differential pairs (prior art, e.g. 8 b/10 b method)

FIG. 2 “Relational” or “LEG” comparator

FIG. 3 Symbol-to-tuple converter: parallel “LEG” comparators

FIG. 4 Transmitter analog ground recovery

### DRAWING REFERENCES

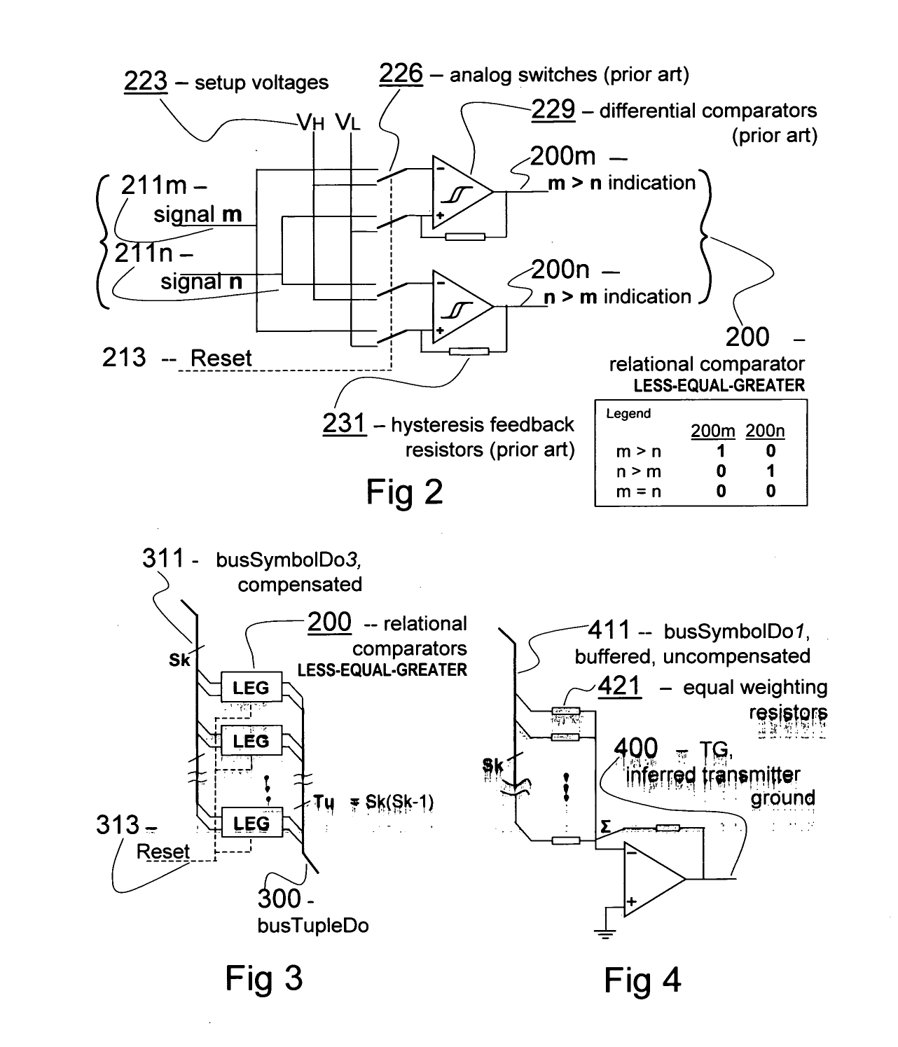

131 Termination resistors of “three-skein” termination
132 “Softpairs” of a “three-skein”
133 Nodal point of “three-skein” termination
141 Termination resistors of “four-skein” termination
142 “Softpairs” of a “four-skein”
143 Nodal point of “four-skein” termination
151 Termination resistors of “five-skein” termination
152 Leftmost, rightmost canonical “softpairs” of a “five-skein”
153 Nodal point of “five-skein” termination
161 Termination resistors of (hardpaired) classical differential pairs
200 “LEG” comparator (FIG. 2, FIG. 3)
200m Digital output: lower-numbered “softpair” member
200n Digital output: higher-numbered “softpair” member
211m Analog input: lower-numbered “softpair” member
211n Analog input: higher-numbered “softpair” member
213 Setup signal input
223 Setup voltages
226 Setup switches (analog gates)
229 Differential comparators
231 Hysteresis resistors, feedback to differential comparator input
300 busTupleDo, relational domain internal bus
313 Setup signal input
400 TG, recovered transmitter ground
411 busSymbolDo1—buffered, uncompensated “skein” voltage signals
421 Weighting resistors, all equal
   Tables

Tables and Glossary conclude DETAILED DESCRIPTION division.
Table 1.1 Symbol patterns and counts, “three-skein”
Table 1.2 Symbol patterns and counts, “four-skein”
Table 1.3 Symbol patterns and counts, “five-skein”
Table 2.1 Symbol assignments, “three-skein” example
Table 2.2 Symbol assignments, “four-skein” example
Glossary

### DETAILED DESCRIPTION

### Introduction

Practicing the present invention presumes a sender device constructed in light of the specifics of the receiving apparatus. This is completely a matter of the rules by which a “relational skein” receiving device operates. A sender might be built in several ways, each correctly interacting with the invention for the purpose of electronic communication. Such construction, while decidedly non-trivial, will be a matter quite derivative from this description and hence will not be explicitly specified here. Nevertheless, anyone setting out to build such a sender device is here given complete disclosure of all interactions with the invention that are essential to practicing it to useful purpose.

Similarly, the invention is but the front end of a complete receive-side partner in the overall communications task. Complete disclosure of how this new “relational signaling” concept impacts client components, deeper in from the conducting medium, is given here.

### DETAILED DESCRIPTION

### Disclosure

Relational “skein”

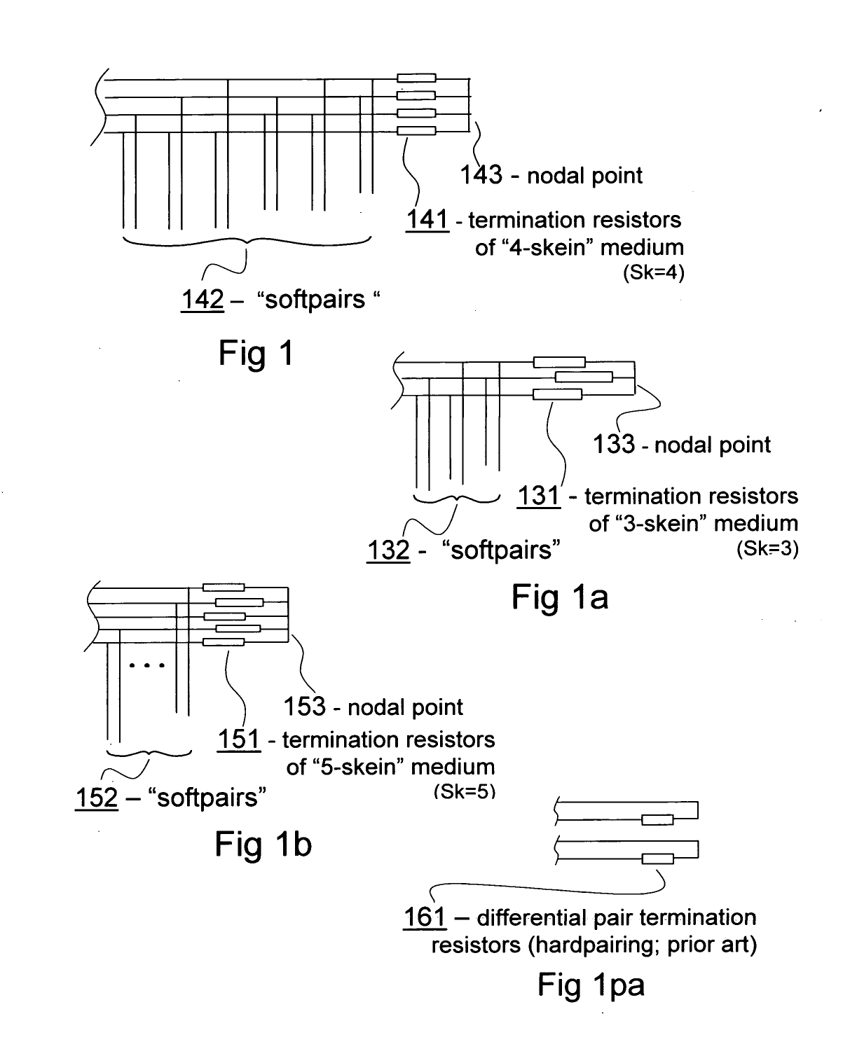

FIGS. 1 1a 1b show differential “skein” termination configurations carried up to “skein” degree 5. “Skeins” of higher degree are of utility and are simply not exemplified.

FIG. 1b, a three-wire configuration, will be recognized as the “wye” of classical AC three-phase power distribution. “Delta” or “deltoid” terminations might be used to create such “skeins,” or a bulk resistive body of a composite material such as cermet, bonded to conductors symmetrically, but to no advantage. Such terminations, while physically symmetrical, fail of electrical symmetry above the three-wire configuration, so they are not preferred embodiment.

Nodal points 133 143 153 in the resistor configurations are key to the electrical symmetry required for “relational signaling.”

Resistors 131 141 151 are to be chosen for the cable's measured characteristic impedance, and closely matched.

“Softpairs” 132 are three in number in a “three-skein,” all shown in FIG. 1a; likewise the six “softpairs” 142 of a “four-skein” in FIG. 1. FIG. 1b shows a “five-skein” termination. Representative “softpairs” 152 are indicated, and ellipsis [ . . . ] calls attention to unindicated “softpairs” to be ordered in the manner of FIG. 1. A “relational skein” of Sk conductors has Sk(Sk−1)/2 “softpairs,” so a “five-skein” is considered to have ten “softpairs.”

Electrical nodal points 133 143 153 and closely equal-value resistors 131 141 151 assure the electrical symmetry needed to configure a “skein” of wires as a medium for “relational signaling” (LESS-EQUAL-GREATER voltages; <, =, >).

Physical runs of “skein” medium are to be terminated at points corresponding to where differential pairs of prior art have their impedance-match terminations, namely at physical run extremes, where impedance matching is needed to prevent energy reflexions that would interfere with intended signals.

Prior art FIG. 1pa, for reference, shows the classic differential pair termination in resistors 161, seen here as two such pairs. This is the medium for 10/100 Ethernet, USB, Firewire, and SATA, all using the 8 b/10 b signaling method. Four such pairs are the medium for Gigabit Ethernet (PAM5 method).

“Relational/LEG” Comparator (FIG. 2)

FIG. 2 shows two differential comparators 229 (DIFF COMPs, prior art) configured as a “relational comparator” or “LEG” comparator 200 to extract relational as well as differential information regarding two input voltages 211m 211n. Hysteresis resistors 231 are essential to that purpose, as will be explained further on in the “Operation” section. The conversion result appears at outputs 200m 200n.

Each conversion requires a setup phase, initiated and relieved by a pulse at Reset input 213. During Reset, setup voltages 223 are applied through analog switches 226 at DIFF COMP 229 inputs instead of signals 211m 211n to be compared.

Analog DIFF COMPs are designed to report which of two input voltages is the greater. A “LEG” comparator is further required to tell whether two voltages are, perhaps, equal. This is makes available the full encoding freedom of a “skein's” relational state space.

A “LEG” comparator exploits hysteresis in DIFF COMPs to do its job. How a “LEG” comparator works is explained further on.

Symbol-to-Tuple Conversion (FIG. 3)

Internal buses 300 311 411 seen in FIGS. 3 and 4 are shown as heavier lines than for single traces, marked with a diagonal slash across, somewhere along the line. Often the number of lines in the bus is noted near the bus slash. This convention tells the reader that several traces run along together, allied enough in purpose to be given a composite name as a bus.

For example, we see two internal buses in FIG. 3. Internal bus busSymbolDo 311 carries signals from the analog medium to be converted to the digital domain. This bus has Sk traces, corresponding to the wires of the “skein” medium. The converted digital information is fed into a second internal bus, busTupleDo 300. The tuple bus has more traces than the symbol bus, two for each “softpair,” Tu=Sk(Sk−1).

FIG. 3, then, shows a gang of “LEG” comparators 200, one for each “softpair,” converting symbols as they arrive on internal bus, busSymbolDo 311. Converted to digital domain as tuples, they are fed to client devices on internal busTupleDo 300.

Reset signal 213 needed by “LEG” comparators 200 is supplied at Reset input 313.

Transmitter Ground Recovery (FIG. 4)

FIG. 4 shows a summing junction OP AMP, set up to sum all of the voltages appearing on the uncompensated lines of busSymbolDo 411 of a “skein.” Weighting resistors 421 provide that each line contribute equally to the sum, which in turn is presented to client devices at OP AMP output TG 400.

### DETAILED DESCRIPTION

### Operation

Symbol Assignment: the Three-Spaces Partition

Tables 2.1 2.2 give symbol encodings to granules of data and to special codes. Partitioning for that distinction makes three denotation spaces: data, specials, and <Depo>.

To facilitate matters, we construct tables in such a way that complementing the symbol of a special shall never result in a data symbol, and vice-versa. <Depo>—all conductors grounded—is uniquely the symbol whose relational-domain complement is itself. It is in a complementation closure space of one member. Hence <Depo> should not be made available for encoding data or specials.

Tables 2.1 2.2 show complementation closure. It might seem strange to say <Depo> has no complement. Note that voltage symbols are only distinct relationally—that is, an overall voltage shift may even shift the static DC balance yet fail to produce a different symbol because of relational aliasing. The pattern 3 −3 −1 1 is indistinguishable from 2 −2 −1 1 to a relational discriminator (DC balance zero for both). Likewise 0 0 0 0 is aliased by 2 2 2 2 as well as by 3 −3 −3 −3 and numerous other voltage-shifted symbols, so <Depo> (all zeroes for whatever “skein” degree) has no complement in the relational domain other than itself.

A fundamental requirement for “relational skein” technology to operate usefully is some mechanism for repeating a granule of data other than by re-sending its symbol in the stream. Simply reiterating a symbol would appear as merely one prolonged symbol rather than two separate ones, since no change appears on the medium.

In “granny gear,” used in administrative and tuning exchanges, the depolarizing null symbol follows every symbol sent. Asserting <Depo> after every symbol assures a state change no matter if repeats occur.

However, for routinely repeating a granule of data, a special symbol, <Ditto>, is sent in place of a granule just sent under its assigned symbol. If a third consecutive occurrence of the same data granule should happen to come next in the data stream, it is, of course, sent under its assigned symbol as usual. This is always valid, since symbol change is guaranteed at that point by the Three-Spaces Partition.

A data stream can show long runs of monotonous data which, by their regularity, emit EMI if encoded as-is. EMI of this kind is much lessened by scrambling, in a pseudo-random technique such as FSR. FSR is readily applied to “relational” signaling and is preferred embodiment. Additionally, pseudo-randomizing works against line polarization.

Tables 2.1 2.2 show suggested symbol assignments for a three-wire or four-wire “relational skein” medium. Such a table is the starting-point for building a granule lookup table for a receiver, and for building a corresponding sender-side lookup table.

A symbol table is not given for “five-skein” embodiments or higher, as that task is better given to a computer program. However, Table 1.3 gives the “five-skein” patterns and counts as for the “skeins” of lower degree.

Building Lookup Tables for Sender, Receiver

Unfortunately, receive-side and transmit-side lookup tables will not be interchangeable. To build them separately and then check by hand for proper co-operativity would be an error-prone process in 4-wire and 5-wire embodiment, since the lookup needs of sender and receiver are quite different. In particular, the send-side environment need know nothing of “relational” tuples. Lookup tables should therefore be built automatically, from a common source mechanism, beginning with a mapping of granules in the domain of data and specials, to symbols in the domain of patterns of absolute voltages on conductors (of primary interest only to sender). Once a sender-side mapping is defined, a corresponding receive-side mapping of tuples to granules can proceed.

Relational domain is that in which voltage symbols as such are not immediately discernible, but only patterns of pairwise relational comparison, unique to each symbol. Thus the signaling state of each “softpair” on a “skein” medium is reflected in a corresponding 2-bit unit in a tuple. As noted above, a “skein” of Sk conductors will require receive-side granule lookup by tuples of bit width Tu=Sk(Sk−1).

Canonical Ordering of “Softpairs”

It will be necessary to settle on a canonical order in which to arrange “softpairs” and their 2-bit indications for schematizing into tuples. Numbering the conductors of a “relational skein” from 1 to Sk, pairs with lower-left number take precedence, left-to-right. The right member of a pair advances more rapidly, in conventional “least significant digit” style:
1,2 1,3 1,4 . . . 1,Sk 2,3 2,4 . . . 2,Sk 3,4 . . . 3,Sk . . . (Sk−1),Sk

Note, in both tables, that because items of lower arity are incorporated into spaces of higher maximum arity, sign-extension may be needed in looking up a symbol by its granule unless larger lookup storage is available. In constructing a lookup table for send-side use, an additional bit will be required, to distinguish specials from data. In the reverse lookup, further bits will be useful to receive-side processing for quickly identifying certain particular specials such as <EoCRC>. Pre-eminently, <Ditto>, and Null specials such as <Depo>, need each its own orthogonal single-bit lookup support, as they are to be acted upon in early intake, transparent to higher processing.

Special codes that may be required by any particular protocol or named bus (Firewire, Ethernet, . . . ) are accommodated in two ways, explicit and escaped. Unassigned explicit specials are available (Tables 1 2). Should more than these be needed, one may be designated <Esc> to give one or two subsequent granules special meaning, or two may be designated <{> and <}> for bracketing sidestream information, reminiscent of the antique SHIFT-OUT, SHIFT-IN of telegraphy.

Preferred arities for four-wire and five-wire embodiments are 2-ary, 3-ary and 4-ary only. Use of 5-ary encoding in five-wire embodiment is cautioned as perhaps not conferring enough advantage—9 bits/transition versus 8 bits/tr—to justify an expected lessened signal robustness in the face of line polarization and attenuation. However, on shorter runs, or in a communications channel totally within a semiconductor or similar ultra-small, ultra-dense device (such as a 3D storage lattice), 5-ary encoding may be a good choice.

Operation—“LEG” comparator (FIG. 2)

The “LEG” comparator (FIG. 2) is at the heart of communications on a “skein” medium. It gives the essentials of the “relational” state of two lines of the medium quickly, cheaply, in a way fairly resistant to noise, polarization and signal degradation, and in digital form for further processing.

A “LEG” comparator comprises two differential comparators 229 (DIFF COMPs; prior art). A DIFF COMP is a specialized OP AMP designed with its inputs in the analog or linear domain and its output in the digital domain. At the output, 1 says the non-inverting (+) input sees the greater voltage, or 0 says the inverting (−) input sees the greater voltage.

The DIFF COMP is to keep its output value always slammed to minimum or maximum voltage, usually those voltages used for 0 and 1 by the digital circuitry of a system. It is to spend almost no time in changing from one to the other state. To keep a DIFF COMP to its proper slam-to-digital output behavior, never locking up in indecision over which of its two inputs is the greater, a small amount of hysteresis is often added.

Hysteresis 231 used in the “LEG” comparator is considerably greater than a tiny nudge-off-indecision, anti-oscillation amount. We set the tightness/looseness of the EQUAL test by the amount of hysteresis: a higher resistance 231 gives a tighter test.

Hysteresis creates a rule about what it takes to produce a change from a DIFF COMP. The rule is that the two voltages being compared have to reverse their comparative sense (greater/less) by a definite set amount before the differential answer will change.

As example, in detail: Say we have set hysteresis at 10% of full voltage swing (10% fs), and voltage m happens just now to be above voltage n by 15% fs. The DIFF COMP's output, the answer to m>n? is 1, or True. Now suppose voltage m falls by 15% fs while n remains steady, bringing the two equal. The yes-no answer to m>n? does not change, because the change did not completely traverse the hysteresis zone. Now suppose voltage m falls below n by 8% fs. Still no change in the answer, by the same rule that hysteresis enforces.

Essential to the purpose then, the two voltages merely becoming equal is not enough to change the answer. Not even reversing is sufficient unless the reversal exceeds the amount set by hysteresis. Once the answer does change, the hysteresis rule is still in force, but now in reverse sense. As before, m, n merely becoming equal cannot change the new answer. In all this, there is no requirement for one or the other voltage to remain steady. They both may change in various ways, but the only changes that affect the differential answer are these more-than-reversals.

The appearance of 0 0 at “LEG” comparator outputs 200m 200n informs client-level processing that the two voltages are equal—equal, that is, within the tolerance set by hysteresis. In this context, 0 0 is digital indication for “No, m is not greater than n, and No, n is not greater than m.” There is but one conclusion to be drawn from these two differential results: m=n.

Differences from Prior Art

Note that the device has now diagnosed equality of voltages without reference to any voltage other than each two presented directly on a “softpair” of the “skein,” and (optionally) without resorting to analog-to-digital conversion. Besides the unique “skein” medium itself, this distinguishes “relational” signaling from broadly similar pulse amplitude modulation techniques of prior art.

This also highlights an essential difference from PAM5 technique, in which a “marker voltage” is sent as a reference for signal voltages on its pair, which is stored for later reference and periodically updated to compensate for possibly different conditions of signal energy loss.

PAM5 compares signals to the marker reference as signed values. In contrast, “relational” signals are compared in differential mode—a simpler method, easier to decode, and one which can be expected to be reliable over greater distances.

Tightness of LESS-EQUAL-GREATER Equality Test

To be useful, the equality test of a “LEG” comparator needs to have some looseness, because “there's many a slip twixt cup and lip.” Signals will not be progressively weakened (attenuated) to exactly the same degree in their travel along a physical medium. Worse, if not addressed, polarization can build up and distort one wire's voltage signal out of its intended relation with the others. A very tight equality test would obviously not be useful.

On the other hand, the equality test should not be too loose. Too loose a test would allow voltages intended to be unequal to be falsely reported-equal (or vice-versa) when uneven attenuation and polarization combine to distort signal over long distance. The total voltage headroom chosen needs to be planned, giving a zone of inequality between each zone of equality, the U/E ratio. Practical U/E values are probably in the range 2 to 5.

Looseness (tightness) of the EQUAL test in the “LEG” comparator is implemented as hysteresis 231, added (prior art) to differential comparators 229 as feedback of a portion of output, fed around to the non-inverting input (+) through a resistance which determines the portion of feedback sample (prior art, provided by feedback elements 231.

Providing adjustability to hysteresis 231 was considered, to be graded to the arity agreed between communicating parties on the medium according to conditions of the moment. However, such is not preferred embodiment. That degree of complexity would be better devoted to polarization compensation and attenuation compensation, discussed along with FIG. 4, and thus accomplish more.

When a “LEG” comparator gets Reset command 213 to prepare for signal conversion, two fixed voltages 223 are temporarily switched through analog gates 226 onto the inputs. This serves to prejudice the two differential results (in a setup phase) in anticipation of how hysteresis is to affect the outcome of a conversion phase.

It is essential to note, in distinction from prior art, that setup voltages 223 are not references in the analog sense. Moreover, they need not even be the extremes of voltages seen on the medium. Any two conveniently different voltages may be used, so long as their comparative sense be known and they differ by substantially more than the greatest hysteresis 231 to be used

Operation—Symbol-to-Tuple Conversion (FIG. 3)

A gang of three “LEG” comparators, one for each “softpair,” will serve symbol-to-tuple conversion for a three-wire embodiment of “skein” medium, or “three-skein.” “Four-skein” and “five-skein” symbol-to-tuple conversion will require parallel gangs of six and ten “LEG” comparators respectively—Sk(Sk−1)/2 in general.

Internal bus, busSymbolDo 311 is Sk bits wide (3, 4, or more, each preferred for different applications). The symbol bus represents the domain of voltage patterns, symbols to be discriminated and transformed to the relational domain, a digital domain where no values other than 0, 1, or composites of these, are recognized.

Internal bus, busSymbolDo 311 will be at least impedance-buffered from the medium in best practice. Additionally, filtering may also be applied, such as a Partial Response Filter (a digital technique, prior art) to compensate for known inter-symbol interference [InterOpPCS].

All components of signal change that compose a new symbol cannot be expected to arrive quite simultaneously (signal time skew). Means to collect all signals into a coherent medium state are various—some synchronous, such as phase-locked loop (PLL) technique, and others asynchronous, such as devoting a comparator to each softpair and driving an XOR-gate with a delay leg to watch for change. The delay leg's resistor would be chosen to provide time-fusion of line signals into one internal signal, supplied to symbol-to-tuple conversion gang (FIG. 3) of “LEG” comparators 200 as Reset 313.

Onset of Reset pulse 313 tells the gang of “LEG” comparators 200 to initialize themselves for a conversion episode. Conversion begins on letoff of Reset pulse 313.

The target domain of this conversion is the relational domain of “LEG” comparisons, a series of two-bit “relational” indications from “LEG” comparators 200 and gathered as internal bus, busTupleDo 300 for action further in at client levels. Symbols on a “skein” of Sk conductors will in general be converted into tuples of bit width Tu=Sk(Sk−1).

Transmitter Ground Recovery (FIG. 4), Basis for Polarization Compensation

While the transmit-side of a communications session is following a rule saying “all impressed voltages shall be in static DC balance,” sum TG 400 will be zero at proper capture time for a symbol. This static balance rule will obtain only during idling and during routine data transfer. Bidding and other bus-contention resolution mechanisms such as collision detection (Ethernet) are exceptions.

Sum TG 400 enables a remote receiver to infer the analog ground effective at the transmitter, to support compensation for line polarization.

Even under polarization, this sum will not depart substantially from its unpolarized status, because a line is polarized mainly by transmitted signals, which are forces that do not throw the nodal voltage 133 143 153 of the “skein” medium away from zero provided the “static DC balance” transmitting rule is observed.

Against this inferred transmitter ground TG 400 reference, polarization will be evident for any given line in peak voltage detection (positive and negative separately, of course) covering a short span of symbols.

Difference between positive and negative peaks, then, may be used in a polarization compensation feedback strategy, allowing greater transmission distances to be achieved.

Operation—Further-In Processing

The composite voltage signal now has been transformed from the symbol domain of the medium, a linear domain, to the digital domain. Its momentary form on busTupleDo 300 is a tuple of bits, grouped into two's by “softpairs.”

In best practice, this tuple corresponds to the transfer symbol for a scrambled form of an intended granule, scrambled before transmission by XOR with a feedback shift register (FSR) for reasons explained above.

Accordingly, the converted tuple will be given as an address/offset into a lookup table, which will return a granule, but in scrambled version. Duly shifting the receive-side FSR to get the same pseudo-random pattern the sender used to scramble the granule, we then XOR the granule with the FSR, which unscrambles the granule to the original value.

Next in from an intake section will be processing designed by the practitioner, on familiar lines. A CRC calculation will be needed, of course, preferably done parallel-fashion unless there is processing speed to burn. PHY to LINK transactions (or PHY to MAC) will be a matter of accommodating the client-level expectations of a particular bus (Ethernet, USB, Firewire, CANbus, ATM point-to-point, . . . ).

TABLE 1.1.
“Three-Skein” symbol patterns and counts

| | | symbol | run- | bits/ |
|---|---|---|---|---|
| arity:type | pattern type | count | tot | tr |
| 1:3 | a a a }# = (3!/3!) = | 1 | | |
| | | (<Depo>) | | |
| 2:21 | a a b }# = (3!/2!) comb(2, 1) = | 6 | 6 | 2 |
| 3:111 | a b c }# = 3! = | 6 | 12 | 3 |

NOTE:
comb(m, n) = m!/n!

TABLE 1.2
“Four-Skein” symbol patterns and counts

| | | symbol | run- | bits/ |
|---|---|---|---|---|
| arity:type | pattern type | count | tot | tr |
| 1:4 | a a a a }# = (4!/4!) = | 1 | | |
| | | (<Depo>) | | |
| 2:22 | a a b b }# = (4!/2!2!) = | 6 | | |
| 2:31 | a a a b }# = (4!/3!) comb(2, 1) = | 8 | 14 | 3 |
| 3:211 | a a b c }# = (4!/2!) comb(3, 1) = | 36 | 50 | 5 |
| 4:1111 | a b c d }# = 4! = | 24 | 74 | 6 |

NOTE:
comb(m, n) = m!/n!

TABLE 1.3
“Five-Skein” symbol patterns and counts

| | | symbol | run- | bits/ |
|---|---|---|---|---|
| arity:type | pattern type | count | tot | tr |
| 1:5 | a a a a a }# = (5!/5!) = | 1 | | |
| | | (<Depo>) | | |
| 2:32 | a a a b b }# = (5!/3!2!) | 20 | | |
| | comb(2, 1) = | | | |
| 2:41 | a a a a b }# = (5!/4!) comb(2, 1) = | 10 | 30 | 4 |
| 3:311 | a a a b c }# = (5!/3!) comb(3, 1) = | 60 | | |
| 3:221 | a a b b c }# = (5!/2!2!) | 90 | 180 | 7 |
| | comb(3, 1) = | | | |
| 4:2111 | a a b c d }# = (5!/2!) comb(4, 1) = | 240 | 420 | 8 |
| 5:11111 | a b c d e }# = 5! = | 120 | 540 | 9 |

NOTE:
comb(m,n) = m!/n!

TABLE 2.1
Symbol voltage assignments, “three-skein” example
Symbol voltages are exemplary only up to signed difference, equality,
and static DC balance (node voltage = 0), accommodated to some
chosen voltage transmit envelope.

| | | | | | | granularity | |
|---|---|---|---|---|---|---|---|
| arity:type | symbol | granule | | ′symbol | ′granule | 2-bit | 3-bit |
| 1:3 | 0 0 0 | 1:000 | <Depo> | (self-complement) | | | |
| 2:21 | 1 1 −2 | 000 | 0 | −1 −1 2 | 111 | 3 | 7 |
| 2:21 | 1 −2 1 | 001 | 1 | −1 2 −1 | 110 | 2 | 6 |
| 2:21 | −2 1 1 | 1:001 | ″ | 2 −1 −1 | 1:110 | <EoX> | |
| 3:111 | 2 −2 0 | 010 | 2 | −2 2 0 | 101 | . | 5 |
| 3:111 | 2 0 −2 | 011 | 3 | −2 0 2 | 100 | . | 4 |
| 3:111 | 0 2 −2 | 1:010 | <Sp30> | 0 −2 2 | 1:101 | <Sp31> | |

NOTE:
′x = complement(x)
NOTE:
granules 1:xxx specials (not data)

TABLE 2.2
Symbol voltage assignments, “four-skein” example

| arity:type | symbol | granule | | ′symbol | ′granule | granularity | | |
|---|---|---|---|---|---|---|---|---|
| 1: | 0 0 0 0 | 1:000000 | <Depo> | (self-complement) | | | | |
| 2:22 | 2 2 −2 −2 | 1:000001 | ″ | −2 −2 2 2 | 1:111110 <EoX> | common | | |
| 2:22 | 2 −2 2 −2 | 1:000010 | <sp22> | −2 2 −2 2 | 1:111101 <sp21> | common | | |
| 2:22 | −2 2 2 −2 | 1:000011 | <Idle3> | 2 −2 −2 2 | 1:111100 <Idle0> | common | | |
| | | | | | | 3-bit | 5-bit | 6-bit |
| 2:31 | 3 −1 −1 −1 | 0 00 000 | 0 | −3 1 1 1 | 1 11 111 | 7 | $1f | $3f |
| 2:31 | −1 3 −1 −1 | 0 00 001 | 1 | 1 −3 1 1 | 1 11 110 | 6 | $1e | $3e |
| 2:31 | −1 −1 3 −1 | 0 00 010 | 2 | 1 1 −3 1 | 1 11 101 | 5 | $1d | $3d |
| 2:31 | −1 −1 −1 3 | 0 00 011 | 3 | 1 1 1 −3 | 1 11 100 | 4 | $1c | $3c |
| 3: | −2 2 0 0 | 0 01 000 | 8 | 2 −2 0 0 | 1 10 111 | . | $17 | $37 |
| 3: | −2 0 2 0 | 0 01 001 | 9 | 2 0 −2 0 | 1 10 110 | . | $16 | $36 |
| 3: | −2 0 0 2 | 0 01 010 | $0a | 2 0 0 −2 | 1 10 101 | . | $15 | $35 |
| 3: | 0 −2 2 0 | 0 01 011 | $0b | 0 2 −2 0 | 1 10 100 | . | $14 | $34 |
| 3: | 0 −2 0 2 | 0 01 100 | $0c | 0 2 0 −2 | 1 10 011 | . | $13 | $33 |
| 3: | 0 0 −2 2 | 0 01 101 | $0d | 0 0 2 −2 | 1 10 010 | . | $12 | $32 |
| 3: | −1 0 −1 2 | 0 01 110 | $0e | 1 0 1 −2 | 1 10 001 | . | $11 | $31 |
| 3: | −1 0 2 −1 | 0 01 111 | $0f | 1 0 −2 1 | 1 10 000 | . | $10 | $30 |
| 3: | 2 0 −1 −1 | 0 11 000 | $18 | −2 0 1 1 | 1 00 111 | . | 7 | $27 |
| 3: | 0 −1 −1 2 | 0 11 001 | $19 | 0 1 1 −2 | 1 00 110 | . | 6 | $26 |
| 3: | 0 −1 2 −1 | 0 11 010 | $1a | 0 1 −2 1 | 1 00 101 | . | 5 | $25 |
| 3: | 0 2 −1 −1 | 0 11 011 | $1b | 0 −2 1 1 | 1 00 100 | . | 4 | $24 |
| 3: | −1 −1 2 0 | 0 11 100 | $1c | 1 1 −2 0 | 1 00 011 | . | 3 | $23 |
| 3: | −1 2 −1 0 | 0 11 101 | $1d | 1 −2 1 0 | 1 00 010 | . | 2 | $22 |
| 3: | 2 −1 −1 0 | 0 11 110 | $1e | −2 1 1 0 | 1 00 001 | . | 1 | $21 |
| 3: | −1 −1 0 2 | 0 11 111 | $1f | 1 1 0 −2 | 1 00 000 | . | 0 | $20 |
| 3: | −1 2 0 −1 | 01 0111 | $17 | 1 −2 0 1 | 10 1000 | . | . | $28 |
| 3: | 2 −1 0 −1 | 01 0110 | $16 | −2 1 0 1 | 10 1001 | . | . | $29 |
| 4: | −3 3 1 −1 | 01 0101 | $15 | 3 −3 −1 1 | 10 1010 | . | . | $2a |
| 4: | −3 1 3 −1 | 01 0100 | $14 | 3 −1 −3 1 | 10 1011 | . | . | $2b |
| 4: | −3 1 −1 3 | 01 0011 | $13 | 3 −1 1 −3 | 10 1100 | . | . | $2c |
| 4: | 1 −3 3 −1 | 01 0010 | $12 | −1 3 −3 1 | 10 1101 | . | . | $2d |
| 4: | 1 −3 −1 3 | 01 0001 | $11 | −1 3 1 −3 | 10 1110 | . | . | $2e |
| 4: | 1 −1 −3 3 | 01 0000 | $10 | −1 1 3 −3 | 10 1111 | . | . | $2f |
| 4: | 3 −3 1 −1 | 00 0100 | 4 | −3 3 −1 1 | 11 1011 | . | . | $3b |
| 4: | 3 1 −3 −1 | 00 0101 | 5 | −3 −1 3 1 | 11 1010 | . | . | $3a |
| 4: | 3 1 −1 −3 | 00 0110 | 6 | −3 −1 1 3 | 11 1001 | . | . | $39 |
| 4: | 1 3 −3 −1 | 00 0111 | 7 | −1 −3 3 1 | 11 1000 | . | . | $38 |
| 4: | 1 3 −1 −3 | 1:00 0001 | <Sp41> | −1 −3 1 3 | 1:11 1110 | | | <Sp42> |
| 4: | 1 −1 3 −3 | 1:00 0011 | <Sp43> | −1 1 −3 3 | 1:11 1100 | | | <Sp40> |

NOTE:
′x = complement(x)
NOTE:
granules 1:xxx specials (not data)

TABLE 2.3
Symbol voltage assignments, “five-skein” and higher

There are too many “five-skein” symbols to write and check
conveniently by hand. This is a job for a computer program,
not supplied.

Glossary
′Value the complement of Value. The complement of ′Value is Value.
arity number of values available to combine as a symbol. Higher arities demand closer discrimination of voltages within a designed max voltage range (headroom) and hence are more susceptible to signal interference and degradation.
binary, 2-ary combination of up to two different values (voltages) for signal encoding
complement pattern formed by inverting all elements: ′granule all 0's changed to 1, all 1's changed to 0 (digital complement) ′symbol all signs reversed (analog, linear, DC complement)
<Depo> special having null semantics, asserted to depolarize the bus medium: all conductors momentarily grounded (driven at zero volts)
differential status {<, >}::{LESS, GREATER} (Compare relational status)
<Ditto> special granule meaning “repeat the just-previous data granule”
granularity size in bits of data grouped as a unit
granule data treated as a unit, or a special of same granularity
LINK organizational level of the communications task just above PHY, as its immediate client level. Similar level may be called MAC—media access control, with PHY a sublevel within MAC.
quaternary, 4-ary combination of up to four different voltages for signal encoding
quinary, 5-ary combination of up to five different voltages. PAM5 signaling is in quinary encoding.
relational status {<, =, >}::{LESS, EQUAL, GREATER} (Compare Differential Status)
semantics behavior change or action to be taken upon receiving some syntactic construct—the “what said” of communication
Sk skein degree; number of conductors in the unitary medium
skein more than two conductors symmetrically provided with means for preventing unwanted signal reflexion, serving as a unitary medium for serial communications
softpair particular pair of conductors chosen from a skein
special symbol other than for data
symbol (“Relational” signaling) combination of voltages on a differential “skein” representing either a granule of data special code.
syntax the form or grammar in which something is said—the “how said” of communication
ternary, 3-ary combination of up to three different voltages for signal encoding
Tu bit count in a relational tuple; Tu=Sk(Sk−1)
tuple generically, an ordered series of bits. A relational tuple is the analyzed relational form of a symbol. Within the tuple, each softpair is represented by a pair of bits meaning 10: first is greater 01: second is greater 00: equal Bits in a relational tuple have a defined canonical order: 1,2 1,3 1,4 . . . 1,Sk 2,3 2,4 . . . 2,Sk 3,4 . . . 3,Sk . . . (Sk−1),Sk

### CITATIONS

[Fractional2003] U.S. Pat. No. 0,206,578 (2003) “Fractional bit rate encoding in a pulse amplitude modulated (PAM) communications system.”
[InterOpPCS] http://www.iol.unh.edu/training/ge/1000BASE-T/pcs.pdf
[NilssonInOP] Masters Thesis Project of Mattias Nilsson, Department of Signals and Systems, Chalmers University of Technology, Gothenburg, Sweden, on work conducted at Lucent Technologies, Inc Microelectronics Group, Milpetas, Calif., USA
[ViOm1979] “Principles of Digital Communications and Coding” by Andrew J Viterbi and Jim K Omura, McGraw-Hill, Inc 1979

1. Method of terminating more than two conductors for impedance match to prevent signal reflections, comprising resistive elements to the number of said conductors, configured in a radial burst from a common nodal center where a first electrode of each said resistive element is in electrical continuity with all other such first electrodes, the remaining electrodes of said resistive elements being in electrical continuity severally with said conductors, whereby said conductors may function as a serial bus medium or as a serial point-to-point communications medium for relational combinations of voltages.

2. Method of discriminating near-equality versus signed difference, that is, relational discrimination, on two unknown voltages, comprising
(a) a pair of differential comparators having at all times substantially equal hysteresis whereby the tightness of said test for near-equality is set,
(b) means of switching the input electrodes of said pair to be at times operatively connected in agreeing comparative sense to two known voltage levels that differ by decidedly more than said set hysteresis, whereby the method is initialized,
(c) said pair being at other times operatively connected through said switching means in contrary comparative sense to said two unknown voltages, whereby relational discrimination is effected and presented to client devices at the output electrodes of said pair.
